(19) United States
(12) Patent Application Publication
(10) Pub. No.: US 2018/0233484 A1
(43) Pub. Date: Aug. 16, 2018

(54) SEMICONDUCTOR STRUCTURE AND MANUFACTURING METHOD THEREOF

(71) Applicant: NANYA TECHNOLOGY CORPORATION, TAOYUAN CITY (TW)

(72) Inventors: PO-CHUN LIN, CHANGHUA CITY (TW); CHIN-LUNG CHU, TAOYUAN CITY (TW)

(21) Appl. No.: 15/432,329

(22) Filed: Feb. 14, 2017

(51) Int. Cl. H01L 25/065; H01L 21/56; H01L 25/00; H01L 23/00

(52) U.S. Cl. CPC H01L 25/0657; H01L 2224/11462; H01L 25/50; H01L 24/13; H01L 24/16; H01L 24/08; H01L 24/11; H01L 2225/06517; H01L 2225/06562; H01L 2225/06586; H01L 2225/06548; H01L 2224/13016; H01L 2224/16227; H01L 2224/13005; H01L 2224/13139; H01L 2224/13144; H01L 2224/13147; H01L 2224/08145; H01L 21/568

(57) ABSTRACT

A semiconductor structure includes a first die; a second die disposed over or at least partially in contact with the first die; a redistribution layer (RDL) disposed over the second die; a conductive pillar extended between the first die and the RDL; and a molding surrounding the first die, the second die and the conductive pillar, wherein the first die and the RDL are electrically connected by the conductive pillar.

### TECHNICAL FIELD

The present disclosure relates to a semiconductor structure, and particularly relates to several dies stacked over each other and several conductive pillars electrically connecting the dies with a redistribution layer (RDL) in the semiconductor structure. Further, the present disclosure relates to a method of manufacturing the semiconductor structure comprising the stacked dies and the conductive pillars.

### DISCUSSION OF THE BACKGROUND

Semiconductor devices are essential for many modern applications. With the advancement of electronic technology, semiconductor devices are becoming smaller in size while providing greater functionality and comprising greater amounts of integrated circuitry. Due to the miniaturized scale of semiconductor devices, various types and dimensions of semiconductor devices performing different functions are integrated and packaged into a single module. Furthermore, numerous manufacturing operations are implemented for integration of various types of semiconductor devices.

However, the manufacturing and integration of semiconductor devices involve many complicated steps and operations. Integration of a semiconductor device having a low profile and high density becomes increasingly complicated. An increase in complexity of manufacturing and integration of the semiconductor device may cause deficiencies such as poor electrical interconnection, delamination of components, or high yield loss. Accordingly, there is a continuous need to improve the structure and the manufacturing process of semiconductor devices.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure comprising a first die; a second die disposed over or at least partially in contact with the first die; a redistribution layer (RDL) disposed over the second die; a conductive pillar extended between the first die and the RDL; and a molding surrounding the first die, the second die and the conductive pillar, wherein the first die and the RDL are electrically connected by the conductive pillar.

In some embodiments, the first die includes a first surface and a second surface opposite to the first surface, the first surface is at least partially in contact with the second die, and the second surface is at least partially exposed from the molding.

In some embodiments, the second die includes a third surface and a fourth surface opposite to the third surface, the third surface is interfaced with the RDL, and the fourth surface is at least partially in contact with the first die.

In some embodiments, the conductive pillar includes copper, silver or gold.

In some embodiments, a height of the conductive pillar is substantially the same as a thickness of the second die.

In some embodiments, the semiconductor structure further comprises a third die disposed over or at least partially in contact with the first die.

In some embodiments, the semiconductor structure further comprises a second conductive pillar extended between the third die and the RDL or extended between the third die and the second die.

In some embodiments, a height of the second conductive pillar is substantially equal to a total thickness of the first die and the second die.

In some embodiments, the first die is vertically misaligned is with the second die.

In some embodiments, a portion of the first die is protruded from the second die, or a sidewall of the first die is protruded from the second die.

In some embodiments, the RDL includes a dielectric layer at least partially interfaced with the second die and a conductive member surrounded by the dielectric layer.

In some embodiments, the first die includes a first pad disposed over the first die, the second die includes a second pad disposed over the second die, and the first pad is electrically coupled with the second pad.

In some embodiments, a conductive bump is disposed over the RDL.

Another aspect of the present disclosure provides a method of manufacturing a semiconductor structure comprising providing a carrier; disposing a first die over the carrier; disposing a second die over the first die; forming a conductive pillar disposed over and extended from the first die; forming a molding to surround the first die and the second die; forming a redistribution layer (RDL) over the second die and the conductive pillar; and removing the carrier.

In some embodiments, the forming of the conductive pillar includes removing a portion of the molding to form a recess extending towards the first die and disposing a conductive material within the recess to form the conductive pillar.

In some embodiments, the portion of the molding is removed by laser drilling or etching.

In some embodiments, the molding surrounds the conductive pillar.

In some embodiments, the method further comprises disposing a third die over the carrier, wherein the first die is disposed over or at least partially in contact with the third die; and forming a second conductive pillar disposed over the third die and extended from the third die to the RDL or from the third die to the second die.

In some embodiments, the conductive pillar is formed by electroplating.

In some embodiments, the method further comprises disposing a conductive bump over the RDL.

The present disclosure is directed to a semiconductor structure comprising several dies stacked over each other, several conductive pillars extending from one of the dies and electrically connected with a redistribution layer (RDL) or a circuitry disposed under the stacking dies. As such, an overall form factor or size of the semiconductor structure can be minimized or reduced.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a schematic cross-sectional view of a semiconductor structure in accordance with some embodiments of the present disclosure.

FIG. 2 is a schematic cross-sectional view of a semiconductor structure in accordance with some embodiments of the present disclosure.

FIG. 3 is a schematic cross-sectional view of a semiconductor structure in accordance with some embodiments of the present disclosure.

FIG. 4 is a flow chart of a method of manufacturing a semiconductor structure in accordance with some embodiments of the present disclosure.

FIGS. 5 to 15 are schematic views illustrating a process of manufacturing the semiconductor structure by the method of FIG. 4 in accordance with some embodiments of the present disclosure.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

The present disclosure is directed to a semiconductor structure comprising several dies stacked over each other, several conductive pillars extending from one of the dies and electrically connected with a redistribution layer (RDL) or a circuitry disposed under the stacking dies. As such, an overall form factor or size of the semiconductor structure can be minimized or decreased. Also, the present disclosure is directed to a method of manufacturing a semiconductor structure comprising stacking several dies over each other and forming several conductive pillars extending from the dies to electrically connect to a redistribution layer (RDL) or a circuitry disposed under the stacked dies. In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

An electronic device including various semiconductor devices is manufactured by a number of operations. During the manufacturing process, the semiconductor devices with different functionalities and dimensions are integrated into a single module. The semiconductor devices are disposed adjacent to each other, and circuitries of the semiconductor devices are integrated and connected through bonding wire or conductive traces. However, the semiconductor devices manufactured in such configuration are large in size or form factor, which is undesirable.

In the present disclosure, a semiconductor structure is disclosed. The semiconductor structure comprises a redistribution layer (RDL), a first die disposed over the RDL, a second die disposed over the first die and a conductive pillar extended from the second die to the RDL. As a result, an overall form factor or size of the semiconductor structure can be minimized or reduced.

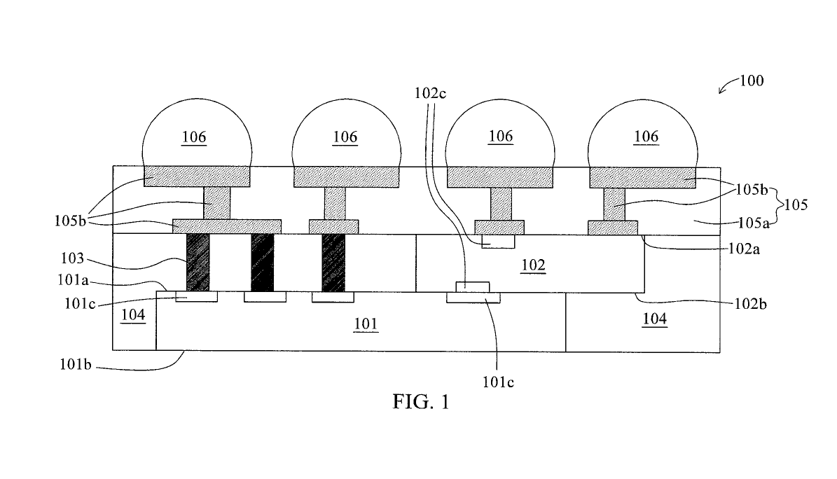

FIG. 1 is a cross-sectional view of a semiconductor structure 100 in accordance with some embodiments of the present disclosure. In some embodiments, the semiconductor structure 100 includes a first die 101, a second die 102, a conductive pillar 103, a molding 104 and a redistribution layer 105.

In some embodiments, the semiconductor structure 100 is a part of a semiconductor package or a semiconductor device. In some embodiments, the semiconductor structure 100 is a semiconductor package or a semiconductor device. In some embodiments, the semiconductor structure 100 is a part of a wafer level multiple chip package (WLMCP). In some embodiments, the semiconductor structure 100 is a WLMCP.

In some embodiments, the first die 101 is a die, a chip or a package. In some embodiments, the first die 101 is fabricated with a predetermined functional circuit within the first die 101 produced by photolithography operations. In some embodiments, the first die 101 is singulated from a semiconductive wafer by a mechanical blade or a laser blade. In some embodiments, the first die 101 comprises a variety of electrical circuits suitable for a particular application. In some embodiments, the electrical circuits include various devices such as transistors, capacitors, resistors, diodes or the like.

In some embodiments, the first die 101 comprises any one of various known types of semiconductor devices such as accelerated processing unit (APU), memories, dynamic random access memory (DRAM), NAND flash memory, central processing unit (CPU), graphic processing unit (GPU), microprocessors, application-specific integrated circuits (ASICs), digital signal processors (DSPs), or the like. In some embodiments, the first die 101 is a logic device die or the like.

In some embodiments, the first die 101 has a quadrilateral, rectangular, square, polygonal or any other suitable shape. In some embodiments, the first die 101 includes a first surface 101a and a second surface 101b opposite to the first surface 101a. In some embodiments, the first surface 101a is a front side or an active side on which the circuits or electrical components are disposed. In some embodiments, the second surface 101b is a back side or an inactive side where the circuits or electrical components are absent.

In some embodiments, a first pad 101c is disposed over the first die 101. In some embodiments, the first pad 101c is disposed over the first surface 101a of the first die 101. In some embodiments, the first pad 101c is electrically connected to a circuitry inside the first die 101. In some embodiments, the first pad 101c is configured to receive a conductive structure. In some embodiments, the first pad 101c is a bond pad. In some embodiments, the first pad 101c includes gold, silver, copper, nickel, tungsten, aluminum, palladium or alloys thereof.

In some embodiments, the second die 102 is disposed over the first die 101. In some embodiments, the second die 102 is disposed over the first surface 101a of the first die 101. In some embodiments, the second die 102 is at least partially in contact with the first die 101. In some embodiments, the second die 102 is at least partially in contact with the first surface 101a of the first die 101. In some embodiments, the first die 101 is vertically misaligned with the second die 102. In some embodiments, the second die 102 is stacked onto the first die 101 in a horizontally shifted manner. In some embodiments, the second die 102 is horizontally shifted from the first die 101. In some embodiments, a portion of the first die 101 is protruded from the second die 102. In some embodiments, a sidewall of the first die 101 is protruded from the second die 102, or a sidewall of the second die 102 is protruded from the first die 101. In some embodiments, the sidewall of the first die 101 is vertically misaligned with the sidewall of the second die 102.

In some embodiments, the second die 102 is a die, a chip or a package. In some embodiments, the second die 102 is fabricated with a predetermined functional circuit within the second die 102 produced by photolithography operations. In some embodiments, the second die 102 is singulated from a semiconductive wafer by a mechanical or laser blade. In some embodiments, the second die 102 comprises a variety of electrical circuits suitable for a particular application. In some embodiments, the electrical circuits include various devices such as transistors, capacitors, resistors, diodes or the like.

In some embodiments, the second die 102 comprises any one of various known types of semiconductor devices such as accelerated processing unit (APU), memories, dynamic random access memory (DRAM), NAND flash memory, central processing unit (CPU), graphic processing unit (GPU), microprocessors, application-specific integrated circuits (ASICs), digital signal processors (DSPs), or the like. In some embodiments, the second die 102 is a logic device die or the like. In some embodiments, the first die 101 and the second die 102 include identical or different types of semiconductor devices.

In some embodiments, the second die 102 has a quadrilateral, rectangular, square, polygonal or any other suitable shape. In some embodiments, the second die 102 includes a third surface 102a and a fourth surface 102b opposite to the third surface 102a. In some embodiments, the third surface 102a is a front side or an active side on which the circuits or electrical components are disposed. In some embodiments, the fourth surface 102b is a back side or an inactive side from which the circuits or electrical components are absent.

In some embodiments, the fourth surface 102b of the second die 102 is at least partially in contact with the first die 101. In some embodiments, the fourth surface 102b of the second die 102 is at least partially in contact with the first surface 101a of the first die 101. In some embodiments, a portion of the fourth surface 102b of the second die 102 is not in contact with the first surface 101a of the first die 101. In some embodiments, a portion of the first surface 101a of the first die 101 is not in contact with the fourth surface 102b of the second die 102.

In some embodiments, a second pad 102c is disposed over the second die 102. In some embodiments, the second pad 102c is disposed over the third surface 102a or the fourth surface 102b of the second die 102. In some embodiments, the second pad 102c is electrically connected to a circuitry inside the second die 102. In some embodiments, the second pad 102c is configured to receive a conductive structure. In some embodiments, the second pad 102c is a bond pad. In some embodiments, the second pad 102c includes gold, silver, copper, nickel, tungsten, aluminum, palladium or alloys thereof.

In some embodiments, the first pad 101c is electrically coupled with the second pad 102c. In some embodiments, the second pad 102c disposed on the fourth surface 102b of the second die 102 is electrically coupled with the first pad 101c disposed on the first surface 101a of the first die 101, such that a circuitry of the first die 101 is electrically connected to a circuitry of the second die 102.

In some embodiments, the conductive pillar 103 is extended from the first die 101. In some embodiments, the conductive pillar 103 is disposed over and protruded from the first surface 101a of the first die 101. In some embodiments, the conductive pillar 103 is disposed over a die pad or a terminal of the first die 101 and electrically connects the die pad or the terminal to a component external to the first die 101. In some embodiments, the conductive pillar 103 includes conductive material such as copper, silver, or gold. In some embodiments, the conductive pillar 103 is of a cylindrical shape. In some embodiments, a cross section of the conductive pillar 103 is of a circular, rectangular, quadrilateral or polygonal shape. In some embodiments, a height of the conductive pillar 103 is substantially the same as a thickness of the second die 102.

In some embodiments, the conductive pillar 103 is extended from and is electrically coupled with the first pad 101c disposed on the first surface 101a of the first die 101. In some embodiments, the conductive pillar 103 is electrically connected to a circuitry of the first die 101 through the first pad 101c.

In some embodiments, the molding 104 surrounds the first die 101, the second die 102 and the conductive pillar 103. In some embodiments, the molding 104 can be a single-layer film or a composite stack. In some embodiments, the molding 104 includes various materials, such as molding compound, molding underfill, epoxy, resin, or the like. In some embodiments, the molding 104 has a high thermal conductivity, a low moisture absorption rate and a high flexural strength.

In some embodiments, the second surface 101b of the first die 101 is at least partially exposed from the molding 104. In some embodiments, a portion of the molding 104 interfaces with the first surface 101a and a sidewall of the first die 101, the fourth surface 102b and a sidewall of the second die 102, and an outer surface of the conductive pillar 103.

In some embodiments, the RDL 105 is disposed over the second die 102, the conductive pillar 103 and the molding 104. In some embodiments, the RDL 105 is disposed over the third surface 102a of the second die 102. In some embodiments, the conductive pillar 103 is extended between the first die 101 and the RDL 105. In some embodiments, the conductive pillar 103 is electrically connected to the RDL 105. In some embodiments, the first die 101 and the RDL 105 are electrically connected by the conductive pillar 103. In some embodiments, the second die 102 is electrically connected to the RDL 105 through the second pad 102c disposed on the third surface 102a of the second die 102. In some embodiments, the third surface 102a of the second die 102 is at least partially in contact with the RDL 105.

In some embodiments, the RDL 105 is configured to re-route a path of circuitry from the first die 101 or the second die 102 to components external to the first die 101 and the second die 102, so as to redistribute I/O terminals of the first die 101 or the second die 102 over the molding 104. In some embodiments, the RDL 105 is a post passivation interconnect (PPI).

In some embodiments, the RDL 105 includes a dielectric layer 105a and a conductive member 105b. In some embodiments, the dielectric layer 105a is disposed over the second die 102, the conductive pillar 103 and the molding 104. In some embodiments, the dielectric layer 105a is at least partially interfaced with the second die 102. In some embodiments, the dielectric layer 105a is disposed over the third surface 102a of the second die 102. In some embodiments, the dielectric layer 105a includes dielectric materials, such as oxide, nitride, polymer or the like.

In some embodiments, the conductive member 105b is surrounded by the dielectric layer 105a. In some embodiments, the conductive member 105b is partially exposed from the dielectric layer 105a. In some embodiments, the conductive member 105b is partially exposed through the dielectric layer 105a in order to electrically connect to the first die 101, the second die 102 or the conductive pillar 103. In some embodiments, the conductive member 105b is electrically coupled with the conductive pillar 103 or the second pad 102c of the second die 102, so as to electrically connect to the first die 101 through the conductive pillar 103 or to the second die 102 through the second pad 102c. In some embodiments, the conductive member 105b includes conductive material such as gold, silver, copper, nickel, tungsten, aluminum, palladium and/or alloys thereof.

In some embodiments, the semiconductor structure 100 includes a conductive bump 106 disposed over the RDL 105. In some embodiments, the conductive bump 106 is electrically connected to the first die 101, the second die 102 or the conductive pillar 103 through the RDL 105. In some embodiments, the conductive bump 106 is electrically coupled with the conductive member 105b of the RDL 105. In some embodiments, the conductive bump 106 includes conductive material such as solder, copper, nickel, or gold. In some embodiments, the conductive bump 106 is a solder ball, a ball grid array (BGA) ball, a controlled collapse chip connection (C4) bump, a microbump, a pillar or the like. In some embodiments, the conductive bump 106 has a spherical, hemispherical or cylindrical shape.

In some embodiments, the conductive bump 106 is disposed over a circuit board such as printed circuit board (PCB) or etc. In some embodiments, the conductive bump 106 is electrically coupled with a component or a circuitry of the circuit board, such that the first die 101, the second die 102, the conductive pillar 103 and the conductive member 105b are electrically connected to the circuit board.

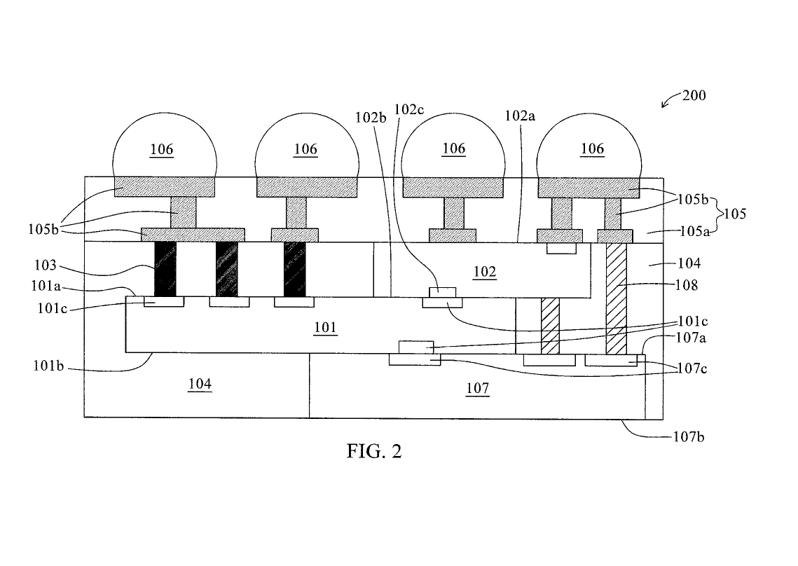

FIG. 2 is a cross-sectional view of a semiconductor structure 200 in accordance with some embodiments of the present disclosure. In some embodiments, the semiconductor structure 200 includes a first die 101, a second die, a conductive pillar 103, a molding 104, an RDL 105 and a conductive bump 106, with a configuration similar to those described above or illustrated in FIG. 1.

In some embodiments, the semiconductor structure 200 includes a third die 107 disposed over the first die 101 and a second conductive pillar 108 extended between the third die 107 and the RDL 105. In some embodiments, the first die 101 is disposed over and at least partially in contact with the third die 107. In some embodiments, the first die 101 is disposed within the molding 104, and the third die 107 is surrounded by the molding 104.

In some embodiments, the third die 107 is a die, a chip or a package. In some embodiments, the third die 107 is fabricated with a predetermined functional circuit within the third die 107 produced by photolithography operations. In some embodiments, the third die 107 is singulated from a semiconductive wafer by a mechanical blade or a laser blade. In some embodiments, the third die 107 comprises a variety of electrical circuits suitable for a particular application. In some embodiments, the electrical circuits include various devices such as transistors, capacitors, resistors, diodes or the like.

In some embodiments, the third die 107 comprises any one of various known types of semiconductor devices such as accelerated processing unit (APU), memories, dynamic random access memory (DRAM), NAND flash memory, central processing unit (CPU), graphic processing unit (GPU), microprocessors, application-specific integrated circuits (ASICs), digital signal processors (DSPs), or the like. In some embodiments, the third die 107 is a logic device die or the like. In some embodiments, the third die 107 includes identical or different types of semiconductor devices as do the first die 101 and the second die 102.

In some embodiments, the third die 107 has a quadrilateral, rectangular, square, polygonal or any other suitable shape. In some embodiments, the third die 107 includes a fifth surface 107a and a sixth surface 107b opposite to the fifth surface 107a. In some embodiments, the fifth surface 107a is a front side or an active side where the circuits or electrical components are disposed thereon. In some embodiments, the sixth surface 107b is a back side or an inactive side where the circuits or electrical components are absent.

In some embodiments, the fifth surface 107a of the third die 107 is at least partially in contact with the first die 101. In some embodiments, the fifth surface 107a of the third die 107 is at least partially in contact with the second surface 101b of the first die 101. In some embodiments, the sixth surface 107b of the third die 103 is exposed from the molding 104. In some embodiments, a portion of the first die 101 is protruded from the third die 107. In some embodiments, a portion of the third die 107 is protruded from the first die 101. In some embodiments, a sidewall of the first die 101 is protruded from a sidewall of the third die 107. In some embodiments, the sidewall of the third die 107 is protruded from the sidewall of the first die 101.

In some embodiments, a third pad 107c is disposed over the third die 107. In some embodiments, the third pad 107c is disposed over the fifth surface 107a of the third die 107. In some embodiments, the third pad 107c is electrically connected to a circuitry inside the third die 107. In some embodiments, the third pad 107c is configured to receive a conductive structure. In some embodiments, the third pad 107c is a bond pad. In some embodiments, the third pad 107c includes gold, silver, copper, nickel, tungsten, aluminum, palladium or alloys thereof.

In some embodiments, the third pad 107c is electrically coupled with the first pad 101c of the first die 101. In some embodiments, the third pad 107c disposed on the fifth surface 107a is electrically coupled with the first pad 101 disposed on the second surface 101b of the first die 101, such that a circuitry of the first die 101 is electrically connected to a circuitry of the third die 107.

In some embodiments, the second conductive pillar 108 is extended from the third die 107. In some embodiments, the second conductive pillar 108 is disposed over and protruded from the fifth surface 107a of the third die 107. In some embodiments, the second conductive pillar 108 is disposed over a die pad or a terminal of the third die 107 and electrically connects the die pad or the terminal to a component external to the third die 107. In some embodiments, the second conductive pillar 108 is disposed over the third pad 107c on the fifth surface 107a. In some embodiments, the second conductive pillar 108 is extended between the third die 107 and the RDL 105 or between the third die 107 and the second die 102. In some embodiments, the second conductive pillar 108 is extended from and is electrically coupled with the third pad 107c disposed on the fifth surface 107a.

In some embodiments, the second conductive pillar 107 is electrically connected to a circuitry of the third die 107 through the third pad 107c. In some embodiments, the second die 102 and the third die 107 are electrically connected by the second conductive pillar 108. In some embodiments, the third die 107 is electrically connected to the RDL 105 through the second conductive pillar 108. In some embodiments, the second conductive pillar 108 is electrically coupled with the conductive member 105b of the RDL 105.

In some embodiments, the second conductive pillar 108 includes conductive material such as copper, silver, or gold. In some embodiments, the second conductive pillar 107 is of a cylindrical shape. In some embodiments, a cross section of the second conductive pillar 108 is of a circular, rectangular, quadrilateral or polygonal shape. In some embodiments, a height of the second conductive pillar 108 is substantially the same as a thickness of the first die 101 or a total thickness of the first die 101 and the second die 102.

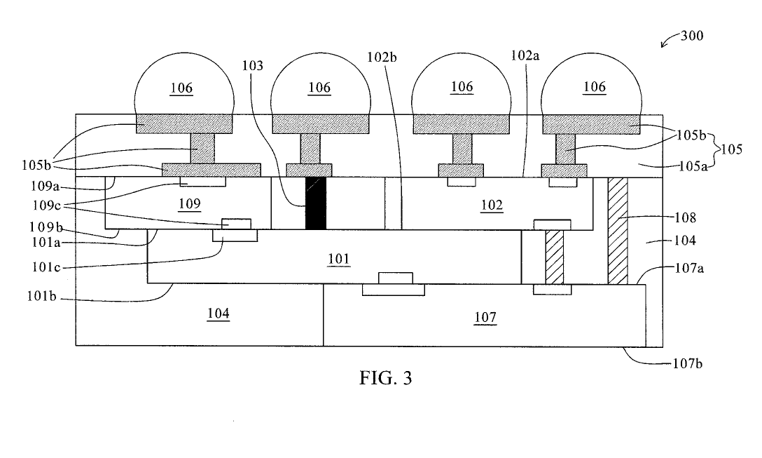

FIG. 3 is a cross-sectional view of a semiconductor structure 300 in accordance with some embodiments of the present disclosure. In some embodiments, the semiconductor structure 300 includes a first die 101, a second die, a conductive pillar 103, a molding 104, an RDL 105, a conductive bump 106, a third die 107 and a second conductive pillar 108, with a configuration similar to those described above or illustrated in FIG. 1 or 2.

In some embodiments, the semiconductor structure 300 includes a fourth die 109 disposed between the first die 101 and the RDL 105. In some embodiments, the fourth die 109 is disposed over and at least partially in contact with the first die 101. In some embodiments, the fourth die 109 is disposed within the molding 104. In some embodiments, the conductive pillar 103 is disposed between the second die 102 and the fourth die 109.

In some embodiments, the fourth die 109 is a die, a chip or a package. In some embodiments, the fourth die 109 is fabricated with a predetermined functional circuit within the fourth die 109 produced by photolithography operations. In some embodiments, the fourth die 109 is singulated from a semiconductive wafer by a mechanical blade or a laser blade. In some embodiments, the fourth die 109 comprises a variety of electrical circuits suitable for a particular application. In some embodiments, the electrical circuits include various devices such as transistors, capacitors, resistors, diodes or the like.

In some embodiments, the fourth die 109 comprises any one of various known types of semiconductor devices such as accelerated processing unit (APU), memories, dynamic random access memory (DRAM), NAND flash memory, central processing unit (CPU), graphic processing unit (GPU), microprocessors, application-specific integrated circuits (ASICs), digital signal processors (DSPs), or the like. In some embodiments, the fourth die 109 is a logic device die or the like. In some embodiments, the fourth die 109 includes identical or different types of semiconductor devices as do the first die 101, the second die 102 and the third die 107.

In some embodiments, the fourth die 109 has a quadrilateral, rectangular, square, polygonal or any other suitable shape. In some embodiments, the fourth die 109 includes a seventh surface 109a and an eighth surface 109b opposite to the seventh surface 109a. In some embodiments, the seventh surface 109a is a front side or an active side on which the circuits or electrical components are disposed. In some embodiments, the eighth surface 109b is a back side or an inactive side from which the circuits or electrical components are absent.

In some embodiments, the seventh surface 109a is at least partially in contact with the RDL 105. In some embodiments, the seventh surface 109a is at least partially in contact with the dielectric layer 105a. In some embodiments, the eighth surface 109b is at least partially in contact with the first die 101. In some embodiments, the eighth surface 109b is at least partially in contact with the first surface 101a of the first die 101.

In some embodiments, a fourth pad 109c is disposed over the fourth die 109. In some embodiments, the fourth pad 109c of the fourth die 109 is disposed over the seventh surface 109a or the eighth surface 109b of the fourth die 109. In some embodiments, the fourth pad 109c disposed over the seventh surface 109a is electrically coupled with the conductive member 105b of the RDL 105. In some embodiments, the fourth pad 109c disposed over the eighth surface 109b is electrically coupled with the first pad 101c of the first die 101.

In some embodiments, the fourth pad 109c is configured to receive a conductive structure. In some embodiments, the fourth pad 109c is a bond pad. In some embodiments, the fourth pad 109c includes gold, silver, copper, nickel, tungsten, aluminum, palladium or alloys thereof.

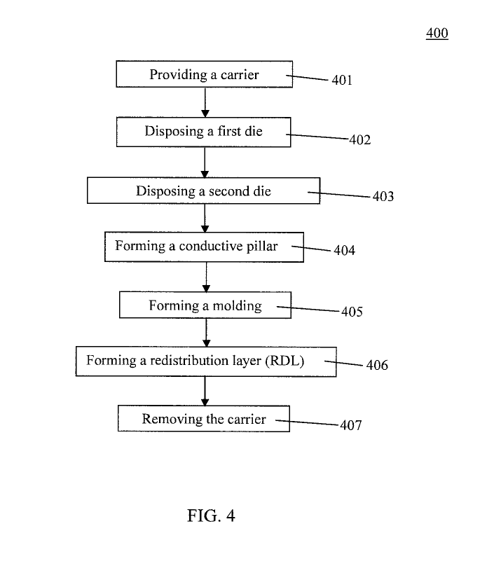

In the present disclosure, a method of manufacturing a semiconductor structure is also disclosed. In some embodiments, the semiconductor structure can be formed by a method 400 as shown in FIG. 4. The method 400 includes a number of operations and the description and illustration are not deemed as a limitation to the sequence of the operations. The method 500 includes a number of steps (401, 402, 403, 404, 405, 406 and 407).

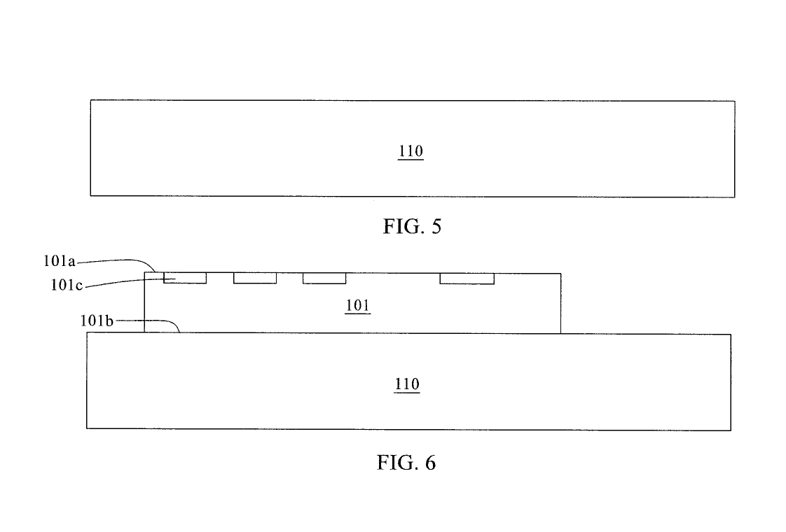

In step 401, a carrier 110 is provided or received as shown in FIG. 5. In some embodiments, the carrier 110 is configured to support a die, a chip or a package. In some embodiments, the carrier 110 is a semiconductive substrate or wafer. In some embodiments, the carrier 110 is a silicon wafer, glass wafer or etc.

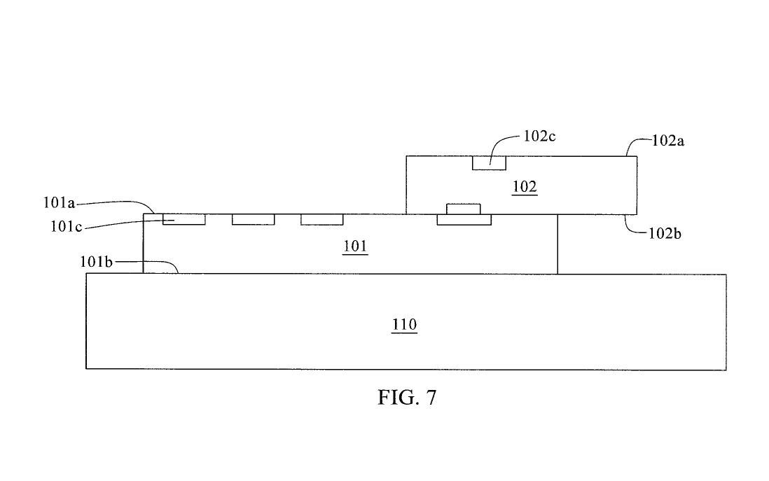

In step 402, a first die 101 is disposed over the carrier 110 as shown in FIG. 6. In some embodiments, the first die 101 includes a first surface 101a and a second surface 101b opposite to the first surface 101a. In some embodiments, the second surface 101b of the first die 101 is disposed over or interfaced with the carrier 110. In some embodiments, the first die 101 is temporarily attached to the carrier 110. In some embodiments, a first pad 101c is disposed over the first surface 101a. In some embodiments, the first die 101 has a configuration similar to those described above or illustrated in any of FIGS. 1 to 3.

In step 403, a second die 102 is disposed over the first die 101 as shown in FIG. 7. In some embodiments, the second die 102 is at least partially in contact with the first die 101. In some embodiments, the first die 101 is vertically misaligned with the second die 102. In some embodiments, the second die 102 includes a third surface 102a and a fourth surface 102b opposite to the third surface 102a. In some embodiments, the fourth surface 102b of the second die 102 is at least partially in contact with the first surface 101a of the first die 101. In some embodiments, a portion of the fourth surface 102b is not in contact with the first surface 101a.

In some embodiments, a second pad 102c is disposed over the third surface 102a or the fourth surface 102b. In some embodiments, the second pad 102c on the fourth surface 102b is electrically coupled with the first pad 101c on the first surface 101a, so as to electrically connect the first die 101 with the second die 102. In some embodiments, the second die 102 has a configuration similar to those described above or illustrated in any of FIGS. 1 to 3.

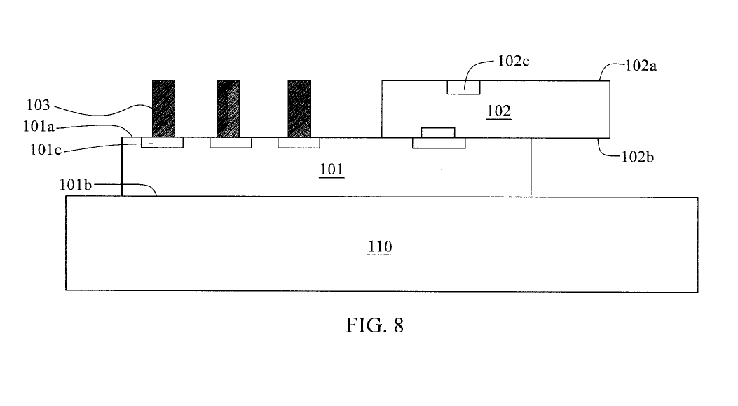

In step 404, a conductive pillar 103 is formed as shown in FIG. 8. In some embodiments, the conductive pillar 103 is disposed over and extended from the first die 101. In some embodiments, the conductive pillar 103 is disposed over the first surface 101a of the first die 101. In some embodiments, the conductive pillar 103 is disposed over the first pad 101c on the first surface 101a. In some embodiments, the conductive pillar 103 is formed by electroplating or any other suitable process. In some embodiments, the conductive pillar 103 includes copper, silver, gold, or the like. In some embodiments, the conductive pillar 103 has a configuration similar to those described above or illustrated in any of FIGS. 1 to 3.

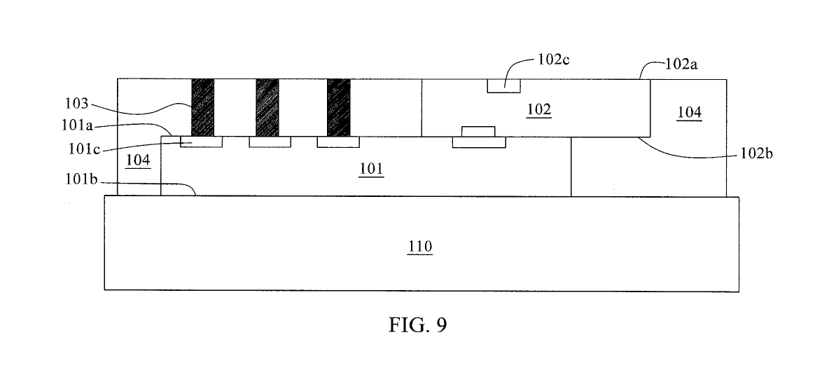

In step 405, a molding 104 is formed as shown in FIG. 9. In some embodiments, the molding 104 is disposed over the carrier 110 and surrounds the first die 101, the second die 102 and the conductive pillar 103. In some embodiments, the molding 104 is formed by compression molding, transfer molding, injection molding or any other suitable process. In some embodiments, some of the molding 104 are ground to expose the conductive pillar 103 and the third surface 102a of the second die 102 after the formation of the molding 104. In some embodiments, the molding 104 has a configuration similar to those described above or illustrated in any of FIGS. 1 to 3.

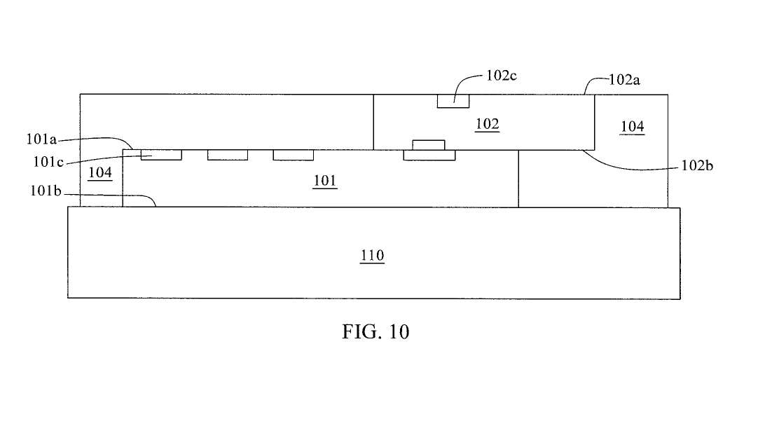

In some embodiments as shown in FIGS. 10 to 12, the conductive pillar 103 is formed after the formation of the molding 104. In some embodiments, the step 405 is implemented prior to the step 404.

In some embodiments, the molding 104 is formed as shown in FIG. 10. In some embodiments, the molding 104 is disposed over the carrier 110 and surrounds the first die 101 and the second die 102. In some embodiments, the molding 104 is formed by compression molding, transfer molding, injection molding or any other suitable process.

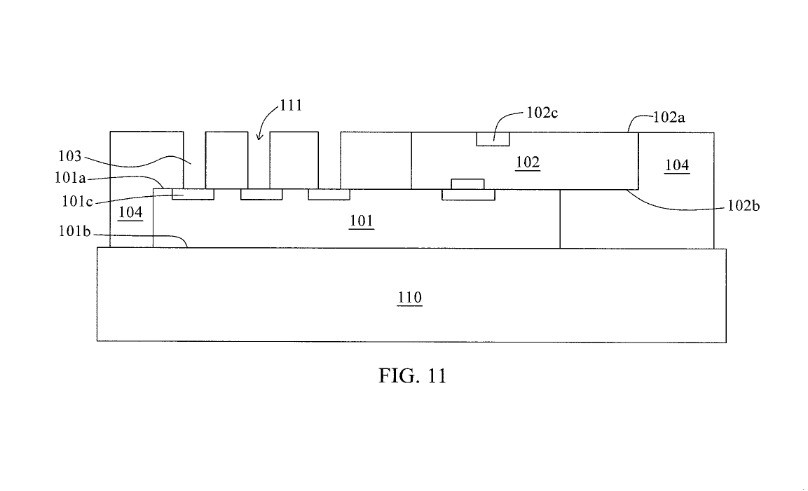

In some embodiments, a portion of the molding 104 is removed to form a recess 111 extending towards the first die 101 as shown in FIG. 11. In some embodiments, the portion of the molding 104 is removed by etching, laser drilling or any other suitable process.

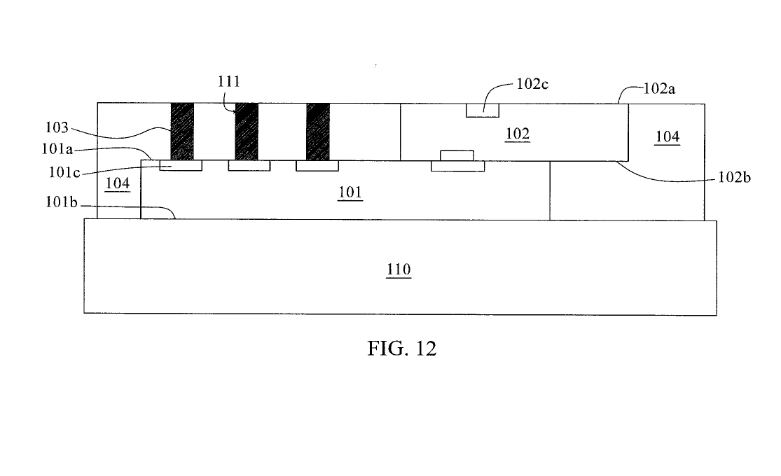

In some embodiments, a conductive material is disposed within the recess 111 to form the conductive pillar 103 as shown in FIG. 12. In some embodiments, the conductive material is disposed by electroplating, sputtering or any other suitable process.

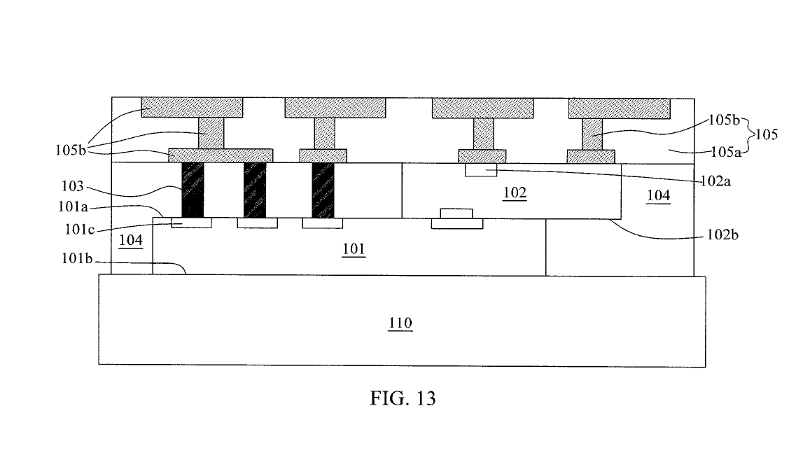

In step 406, an RDL 105 is formed as shown in FIG. 13. In some embodiments, the RDL 105 is formed over the second die 102 and the conductive pillar 103. In some embodiments, the RDL 105 includes a dielectric layer 105a and a conductive member 105b surrounded by the dielectric layer 105a. In some embodiments, the dielectric layer 105a is disposed over the second die 102, the conductive pillar 103 and the molding 104. In some embodiments, the dielectric layer 105a is disposed by spin coating, chemical vapor deposition (CVD) or any other suitable process. In some embodiments, a portion of the dielectric layer 105a is removed and then a conductive material is disposed to fill the dielectric layer 105a being removed to form the conductive member 105b. In some embodiments, the conductive member 105b is extended within the dielectric layer 105a. In some embodiments, the conductive member 105b is electrically coupled with the conductive pillar 103 or the second pad 102c of the second die 102. In some embodiments, the RDL 105 has a configuration similar to those described above or illustrated in any of FIGS. 1 to 3.

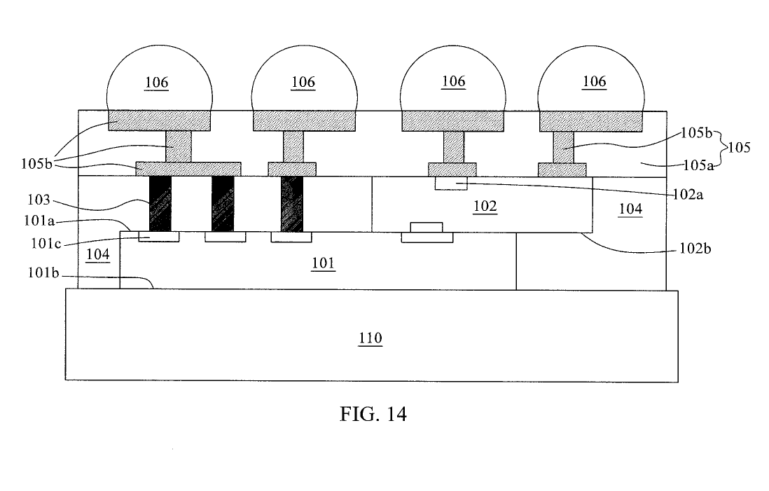

In some embodiments, a conductive bump 106 is disposed over the RDL 105 after the formation of the RDL 105 as shown in FIG. 14. In some embodiments, the conductive bump 106 is disposed over and electrically coupled with the conductive member 105b. In some embodiments, the conductive bump 106 is disposed by ball dropping, solder pasting, stencil printing or any other suitable process. In some embodiments, the conductive bump 106 is heated or reflowed. In some embodiments, the conductive bump 106 has a configuration similar to those described above or illustrated in any of FIGS. 1 to 3.

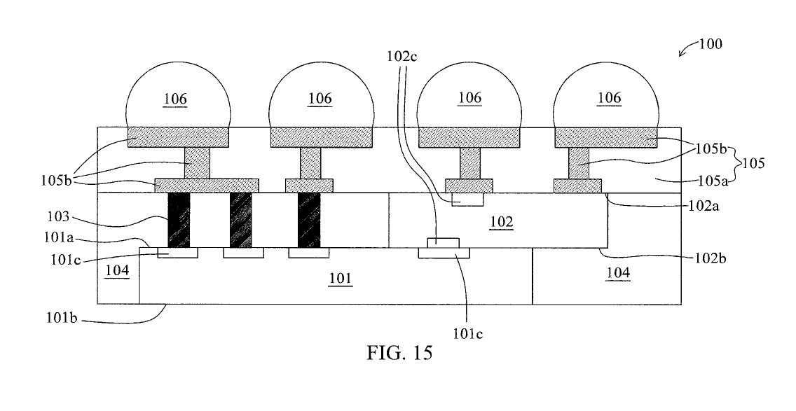

In step 407, the carrier 110 is removed as shown in FIG. 15. In some embodiments, a semiconductor structure 100 is formed, which has a configuration similar to those described above or illustrated in FIG. 1.

In the present disclosure, a semiconductor structure is disclosed. The semiconductor structure comprises a conductive pillar extended between a die and an RDL so as to electrically connect the die with the RDL. Such configuration allows the die to be disposed over another die. Therefore, an overall form factor or size of the semiconductor structure can be minimized or reduced.

A semiconductor structure includes a first die; a second die disposed over or at least partially in contact with the first die; a redistribution layer (RDL) disposed over the second die; a conductive pillar extended between the first die and the RDL; and a molding surrounding the first die, the second die and the conductive pillar, wherein the first die and the RDL are electrically connected by the conductive pillar.

A method of manufacturing a semiconductor structure includes providing a carrier; disposing a first die over the carrier; disposing a second die over the first die; forming a conductive pillar disposed over and extended from the first die; forming a molding to surround the first die and the second die; forming a redistribution layer (RDL) over the second die and the conductive pillar; and removing the carrier.

Although the present disclosure and its advantages have been described in detail, it should be understood that various changes, substitutions and alterations can be made herein without departing from the spirit and scope of the disclosure as defined by the appended to claims. For example, many of the processes discussed above can be implemented through different methods, replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

1. A semiconductor structure, comprising:
a first die;
a second die disposed over and at least partially in contact with the first die;
a redistribution layer (RDL) disposed over the second die;
a conductive pillar extended between the first die and the RDL; and
a molding surrounding the first die, the second die and the conductive pillar,
wherein the first die and the RDL are electrically connected by the conductive pillar, and
wherein a surface of the RDL is in direct interfacing contact with a surface of the second die.

2. The semiconductor structure of claim 1, wherein the first die includes a first surface and a second surface opposite to the first surface, the first surface is at least partially in contact with the second die, and the second surface is at least partially exposed from the molding.

3. The semiconductor structure of claim 1, wherein the second die includes a third surface and a fourth surface opposite to the third surface, the third surface is interfaced with the RDL, and the fourth surface is at least partially in contact with the first die.

4. The semiconductor structure of claim 1, wherein the conductive pillar includes copper, silver or gold.

5. The semiconductor structure of claim 1, wherein a height of the conductive pillar is substantially the same as a thickness of the second die.

6. The semiconductor structure of claim 1, further comprising a third die disposed over or at least partially in contact with the first die.

7. The semiconductor structure of claim 6, further comprising a second conductive pillar extended between the third die and the RDL or extended between the third die and the second die.

8. The semiconductor structure of claim 7, wherein a height of the second conductive pillar is substantially equal to a total thickness of the first die and the second die.

9. The semiconductor structure of claim 1, wherein the first die is vertically misaligned with the second die.

10. The semiconductor structure of claim 1, wherein a portion of the first die is protruded from the second die, or a sidewall of the first die is protruded from the second die.

11. The semiconductor structure of claim 1, wherein the RDL includes a dielectric layer at least partially interfaced with the second die and a conductive member surrounded by the dielectric layer.

12. The semiconductor structure of claim 1, wherein the first die includes a first pad disposed over the first die, the second die includes a second pad disposed over the second die, the first pad is electrically coupled with the second pad.

13. The semiconductor structure of claim 1, wherein a conductive bump is disposed over the RDL.

14. A method of manufacturing a semiconductor structure, comprising:
providing a carrier;
disposing a first die over the carrier;
disposing a second die over and at least partially in contact with the first die;
forming a conductive pillar disposed over and extended from the first die;
forming a molding to surround the first die and the second die;
forming a redistribution layer (RDL) over the second die and the conductive pillar, wherein a surface of the RDL is in direct interfacing contact with a surface of the second die and the conductive pillar; and
removing the carrier.

15. The method of claim 14, wherein the forming of the conductive pillar includes removing a portion of the molding to form a recess extending towards the first die and disposing a conductive material within the recess to form the conductive pillar.

16. The method of claim 15, wherein the portion of the molding is removed by laser drilling or etching.

17. The method of claim 14, wherein the molding surrounds the conductive pillar.

18. The method of claim 14, further comprising:
disposing a third die over the carrier, wherein the first die is disposed over or at least partially in contact with the third die;
forming a second conductive pillar disposed over the third die and extended from the third die to the RDL or from the third die to the second die.

19. The method of claim 14, wherein the conductive pillar is formed by electroplating.

20. The method of claim 14, further comprising disposing a conductive bump over the RDL.
